(19) United States
(12) Patent Application Publication
(10) Pub. No.: US 2015/0114456 A1
(43) Pub. Date: Apr. 30, 2015

(54) METHOD FOR THE PREPARATION OF LOW-DIMENSIONAL MATERIALS

(71) Applicant: Academia Sinica, Taipei (TW)

(72) Inventors: Chih Wei CHU, Taipei (TW); Mohammed Aziz IBRAHEM, Taipei (TW)

(73) Assignee: Academia Sinica, Taipei (TW)

(21) Appl. No.: 14/269,640

(22) Filed: May 5, 2014

(30) Foreign Application Priority Data
Oct. 28, 2013 (TW) 102138955

(51) Int. Cl. C09D 5/24; B02C 17/18; H01L 31/032; C01G 41/00; C01B 19/04; C01G 39/02; C01G 39/06; B02C 23/06; C01B 31/04

(52) U.S. Cl. CPC C09D 5/24; B02C 23/06; B02C 17/18; H01L 31/032; C01B 31/0484; C01B 19/04; C01G 39/02; C01G 39/06; C01G 41/00
USPC 136/252; 423/448; 423/509; 423/606; 252/519.4; 427/58

(57) ABSTRACT

The present invention provides a method for the preparation of low-dimensional materials, comprising mixing a pristine material to be abraded with an organic solvent to form a mixture, abrading the material to be abraded by bead-milling, obtaining a suspension comprising the material of low dimension and the organic solvent, and removing the organic solvent from the suspension to obtain the low-dimensional material.

### BACKGROUND OF THE INVENTION

1. Field of the Invention

The present invention provides a method for the preparation of low-dimensional materials. Suitable materials comprise transition metal dichalcogenides (TMD), metal oxides, and carbonaceous materials. The low-dimensional materials obtained via the method can be applied in various uses, among which the low-dimensional materials of TMD materials have metallic, semi-metallic, or semiconducting properties and can be applied in super lubricants, optical-electronic devices, gas sensors, hydrogen evolution catalysts, and optical sensors.

2. Description of the Related Art

Low-dimensional materials are integrated materials of lattice structures in the shape of a nanosheet (two-dimensional), nanorod (one-dimensional), or nanoparticle (zero-dimensional). According to the concept of quantum effect, the physical properties of low-dimensional materials and bulk materials are completely different. Generally, low-dimensional materials have unique properties and can therefore be widely used to improve functionality in applications compared to bulk materials. Among all the low-dimensional materials, graphene has become the most widely studied two-dimensional (2D) material because of its excellent thermal, electronic, optical and mechanical properties. However, the absence of an energy gap has retarded its application in logic electronics. Therefore, it has become necessary to synthesize graphene analogues of layered inorganic materials that have a finite band gap for the development of next generation nanoelectronics. In recent years, it has been found that the transition metal dichalcogenides (TMD), which are formed by the combination of metals and Group VIA elements and can be of metallic, semi-metallic, and semiconducting materials, are extremely promising building blocks for the development of next generation nanoelectronics. Moreover, unlike the poor mobility of other organic semiconductors, semiconducting TMD materials are well-suited to applications where mobility is important.

TMD materials have the stoichiometry MX₂, wherein M refers to a transition metal, such as tungsten (W), molybdenum (Mo), titanium (Ti), niobium (Nb), and tantalum (Ta), and X refers to sulfur (S), selenium (Se), and tellurium (Te). When the size of the material is changed from bulk (such as powder) to a mono-atomic layer, the band gap changes from indirect band gap to direct band gap, so TMD compounds can be used in various applications, such as super lubricants, super capacitors, batteries, thin film transistors (TFTs), field effect transistors (FETs, enhancement and depletion mode transistors, light emitting diodes (LEDs), gas sensors, hydrogen evolution catalysts, Schocky-barrier solar cells, optical sensors, displays, and transparent electrodes, wherein a new lattice structure of WS₂ can be used as an ideal catalyst in hydrogen evolution reactions (HER) and is a potential replacement of the expensive platinum-based catalyst currently used in polymer thin film electrodes of a fuel cell.

In past studies, many methods for preparing low-dimensional TMD materials were developed, including Scotch tape-assisted micromechanical exfoliation, liquid exfoliation, intercalation-assisted exfoliation, atomic layer deposition, physical vapor deposition, sputtering, atomic layer with chemical vapor deposition, sol gel method, and electrochemical synthesis.

Of these methods, the most well-known method for the preparation of nanoparticle and nanorod materials is the sol gel method. However, the method must be carried out under high pressure and temperature. Moreover, a large amount of materials are consumed during the condensation process, followed by the generation of side products, such as hydroxyls and undesired pores. The sol gel method is complex and time-consuming, causes high consumption of energy and is dangerous. The most commonly seen method for preparation of nanosheet materials is liquid exfoliation carried out by using ionic liquid for the exfoliation and dispersion of materials.

Low-dimensional TMD materials having desirable properties can be prepared by the aforementioned method. However, the method has many drawbacks, such as: it must be carried out in a glove box; the lateral dimension of the products is typically small; the operation conditions must be controlled in high vacuum and under high temperature of 200 to 1200° C. or must involve a long reaction time. Moreover, the semiconducting properties of the TMD materials obtained according to the aforementioned method are variable (H. S, Matte, A. Gomathi, A. L. Manna, D. J. Late, R. Datta, S. K. Pati and C. N. Rao, Angew. Chem. Int, Ed., 2010, 49, 4059-4062; Z. Zeng, T. Sun, J. Zhu, X. Huang, Z. Yin, G. Lu, Z. Fan, O. Yan, H. H. Hng and H. Zhang, Angew. Chem. Int. Ed., 2012, 51, 9052-9056; and X. Rocquefelte, F. Boucher, P. Gressier, G. Ouvrard, P. Blaha and K. Schwarz, phys. Rev. B: Condens. Matter, 2000, 62, 2397-2400). In addition, a third phase surfactant is frequently used in the process of the prior art. However, the use of a surfactant affects the purity of the materials and therefore affects the electrical and optical properties of the final products. On the other hand, most TMD materials are of low solubility, and are only soluble in solvents that are highly toxic and have high boiling points, such as octadecylamine, which makes it difficult for large-scale production of the TMD materials and limits the utility of deposition of the TMD materials to form a film by solution processing.

To solve the technical problems in the existing technology, the applicant provides a method for the preparation of low-dimensional materials by a mechanical milling process. The mechanical power exfoliates the layered TMD materials without affecting their electrical properties. The pristine TMD materials are effectively exfoliated to obtain two-dimensional nanosheet materials. Further, one-dimensional nanorod materials and zero-dimensional nanoparticles are obtained as well. With the selection of suitable solvents, abrading environment and conditions, large amount of nanomaterials can be prepared by a simple process. Nevertheless, the method disclosed in the present application increases the process yield. Compared to the prior art, the method of the present invention is faster, simpler, and cheaper and can fulfill less stringent requirements in terms of ambient environment for preparation, which helps to save energy. The low-dimensional TMD materials obtained according to the method of the present invention can be widely used in materials of various properties and systems of various functionality. The applicant surprisingly found that the method of the present invention is also suitable for use in the preparation of low-dimensional metal oxides and carbonaceous materials.

### SUMMARY OF THE INVENTION

The present invention provides a method for the preparation of a low-dimensional material, comprising:

(i) mixing a pristine material to be abraded with an organic solvent to form a mixture;

(ii) abrading the material to be abraded in the mixture by bead-milling,

(iii) obtaining a suspension comprising the material of low dimension and the organic solvent; and

(iv) removing the organic solvent from the suspension to obtain the low-dimensional material.

The present invention further provides a low-dimensional material suspension, characterized in that the suspension is obtained by mixing a pristine material to be abraded with an organic solvent followed by abrading the material to be abraded in the mixture by bead-milling. Moreover, the low-dimensional material suspension obtained according to the aforementioned method maintains good suspension stability and remains in a suspended state for six months. Such good suspension stability allows the low-dimensional material to be stably stored in the form of a suspension and able to be coated on a substrate by various common liquid processing methods such as spin-coating and ink-jetting for further preparation of low-dimensional material films and electronic devices comprising the low-dimensional materials.

The present invention further provides a method for the preparation of a low-dimensional material film, comprising forming a mixture by mixing a pristine material to be abraded with an organic solvent, abrading the material to be abraded in the mixture by bead-milling to obtain a suspension, coating the suspension on a substrate, and removing the organic solvent from the suspension to obtain the low-dimensional material film. The present invention further provides a low-dimensional material film prepared by the aforementioned method.

The present invention further provides a solar cell comprising the aforementioned low-dimensional TMD material film, wherein the film is used as an electron-extraction film.

### BRIEF DESCRIPTION OF THE DRAWINGS

FIG. 1 shows the structure of a pristine TMD material.

FIG. 2 shows the structure of the wet-milling machine for use in the present invention.

FIGS. 3(a) and (b) are Powder XRD patterns and Raman spectra of pristine NbSe₂ and the nanosheets and nanorods of NbSe₂ (λ_{excitation}=514 nm).

FIG. 4 shows a schematic representation and corresponding SEM images of pristine NbSe₂, NbSe₂ nanosheets, nanorods, and nanoparticles obtained by the method of the present invention.

FIG. 5(a) shows magnetic susceptibility plotted with respect to temperature for the pristine NbSe₂, the NbSe₂ nanosheets, the NbSe₂ nanorods and the NbSe₂ nanoparticles. Inset: magnified view of the superconductivity transition for the NbSe₂ nanorods (left) and nanoparticles (right).

FIG. 5(b) shows the conductivity of a thin film of NbSe₂ nanosheets, nanorods, and nanoparticles plotted with respect to the bending angle.

FIG. 5(c) shows the transmission spectra of films of NbSe₂ nanosheets, nanorods, and nanoparticles measured by Jasco V-670 UV-Vis-NIR spectrometer. Inset: photograph of the (1) bare PET substrate, (2) film of NbSe₂ nanoparticles on PET, (3) film of NbSe₂ nanorods on PET, and (4) film of NbSe₂ nanosheets on PET.

FIGS. 5(d) and (e) are resistance measurements of a flexible electrode coated with NbSe₂ nanosheets subjected to bending, wherein the PET film in FIG. 5(e) is bent at an angle of greater than 60°.

FIG. 6(a) shows XRD patterns of the pristine WS₂ and WS₂ nanosheets.

FIG. 6(b) shows XRD patterns of the pristine MoS₂ and MoS₂ nanosheets.

FIG. 7(a) shows the current density-voltage (J-V) characteristics of the solar cell devices prepared in Example 5. Inset is a dark J-V curves plot.

FIG. 7(b) shows the stability of solar cell devices featuring WS₂ and MoS₂ as electron extraction layers, respectively, measured in terms of the PCE over time. Inset is the inverted device structure.

FIGS. 8(a) and (b) are the UV absorption spectra of (a) a WS₂ thin film and (b) a MoS₂ thin film tested on an ITO substrate.

FIGS. 9(a), (b) and (c) are SEM images of NbSe₂ bulk, nanosheets, and nanorods, respectively.

FIGS. 10(a), (b) and (c) are the SEM images of (a) pristine graphene, (b) graphene nanosheets and (c) graphene nanorods.

FIGS. 11(a), (b), (c) and (d) are the SEM images of (a) pristine MoO₃, (b) MoO₃ nanosheets, (c) MoO₃ nanorods, and (d) MoO₃ nanoparticles.

FIGS. 12(a) and (b) are Raman spectra of pristine WS₂ and MoS₂ and WS₂ and MoS₂ nanosheets (λ_{excitation}=473 nm).

### PREFERRED EMBODIMENT OF THE PRESENT INVENTION

The present invention provides a method for the preparation of low-dimensional materials, comprising:

(i) mixing a pristine material to be abraded with an organic solvent to form a mixture;

(ii) abrading the material to be abraded in the mixture by bead-milling,

(iii) obtaining a suspension comprising the material of low dimension and the organic solvent; and

(iv) removing the organic solvent from the suspension to obtain the low-dimensional material.

In one specific embodiment, the material to be abraded comprises transition metal dichalcogenides, in which the chalcogen comprises sulfur (S), selenium (Se), and tellurium (Te); metal oxides; and carbonaceous materials.

In another specific embodiment, in step (i), the concentration of the material to be abraded in the mixture is 0.01% to 1%, preferably 0.05% to 0.8%, and more preferably 0.2% to 0.5% by total weight of the mixture.

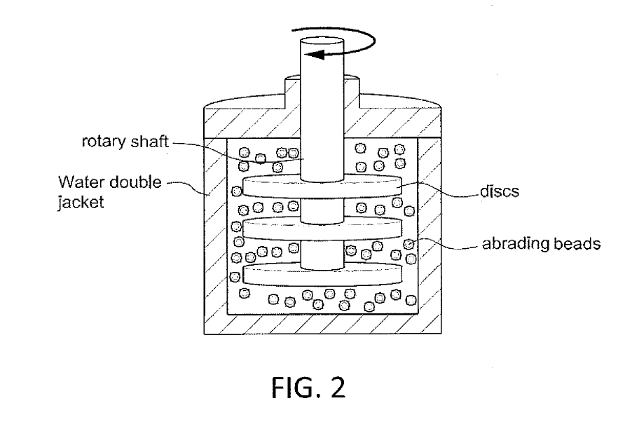

In another specific embodiment, in step (ii), the bead-milling is carried out by feeding the mixture into a wet-milling machine (as shown in FIG. 2) with abrading beads for abrasion, wherein the abrading beads are steel beads, glass beads, or ceramic beads, wherein the ceramic beads are, for example but not limited to zirconia particles or beads, wherein the amount of the abrading beads in the wet-milling machine is about 50% to 80%, preferably 60% to 80%, and more preferably 70% to 80%; the size of the abrading beads is 20 μm to 1 mm, preferably 50 μm to 200 μm, and more preferably 70 μm to 100 μm.

In another specific embodiment, the abrading beads are zirconia particles with a density of 5.95 g/cm³.

In another specific embodiment, in step (ii), when abrasion is carried out by utilizing the wet-milling machine, the speed of the rotating blades in the wet-milling machine is from 10 rpm to 6000 rpm, preferably 1000 rpm to 4000 rpm, and more preferably 1500 rpm to 3000 rpm. A double water-cooled jacket used in the wet-milling machine allows the temperature to be controlled during the abrasion process.

In another specific embodiment, the low-dimensional materials obtained by abrasion are two-dimensional nanosheets, one-dimensional nanorods, or zero-dimensional nanoparticles.

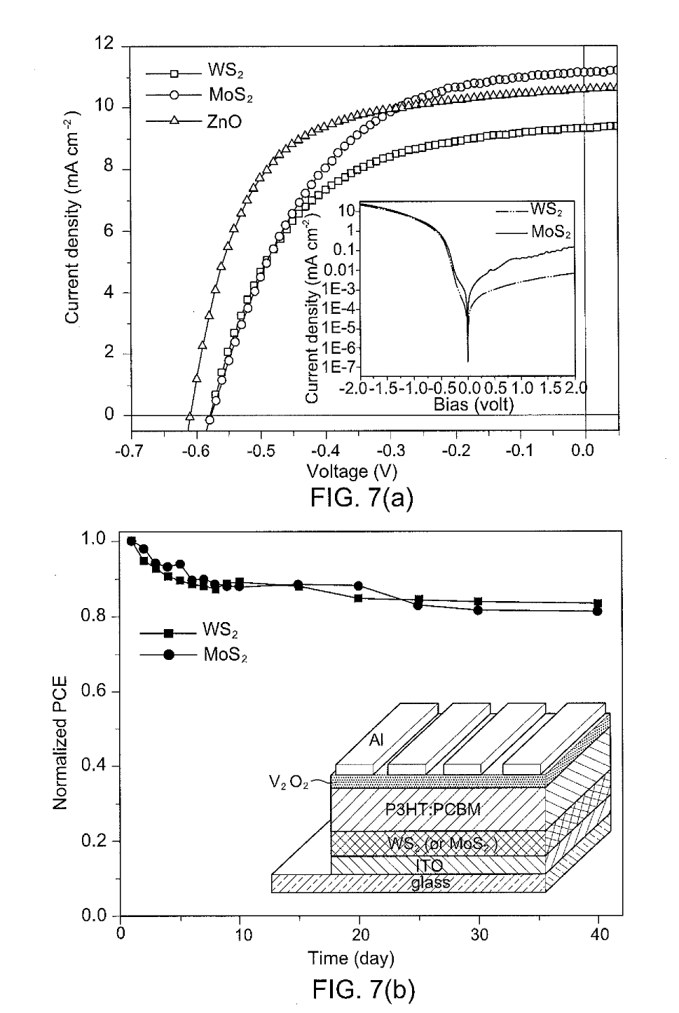

In another specific embodiment, the material to be abraded is NbSe₂. It can be known by using SEM to examine the morphology of NbSe₂ before abrasion and after different abrasion time periods that the pristine NbSe₂ is a bulky structure with a thickness of >100 μm, and the bulky structure is constructed by random networking lamination of two-dimensional sheets. The abraded materials are very thin and separated nanosheets, nanorods, and nanoparticles, as shown in FIGS. 9(a), 9(b) and 9(c). Typical nanosheets have a lateral dimension of 100 nm to 500 nm; nanorods have a length up to 1.2 μm and a diameter of 20 nm to 100 nm; and the nanoparticles have an average particle size of 50 nm to 100 nm.

Different abrasion time periods lead to materials of different dimensions. Moreover, the time periods required for producing different kinds of materials of different dimensions vary in light of the different characteristics of the materials. Taking NbSe₂ as an example, the pristine materials become two-dimensional nanosheets after 4 hours of abrasion, become one-dimensional nanorods after 10 hours of abrasion, and become zero-dimensional nanoparticles after 14 hours of abrasion.

In another specific embodiment, in step (i), the weight ratio of the abrading beads and the organic solvent is from 5:1 to 1:1; preferably 4:1 to 3:1; and more preferably 4:1. In step (ii), the abrasion time period is 30 to 840 minutes; preferably 60 to 600 minutes; and more preferably 120 to 480 minutes.

The organic solvent in the mixture fed into the wet-milling machine comprising the abrading beads is selected from the group consisting of ethylene glycol, N-methylpyrrolidinone (NMP), isopropanol, and combinations thereof. In the case of TMD materials, the solvent is preferably isopropanol or N-methylpyrrolidinone. In the case of metal oxides, the solvent is preferably isopropanol. In the case of carbonaceous materials, the solvent is preferably N-methylpyrrolidinone.

The method of the present invention is easy and fast, and can be reproduced in any lab. In addition, the method of the present invention is not sensitive to ambient gas conditions and therefore does not need to be carried out in a glove box or equipment that controls ambient gas. Moreover, the method of the present invention does not require the use of highly toxic solvents as adopted in the prior art technologies to dissolve the materials to be abraded and does not require the use of flammable substances. Therefore, the method is relatively safe. Besides the aforementioned advantages, the operation power of the wet-milling machine for use in the method of the present invention is only 120 W; that is, the method of the present invention is a low-energy consumption process. The method of the present invention does not require the use of a third phase dispersant (such as a surfactant). The product itself has good suspension ability. Only a little deposition is found after six months of storage time. The low-dimensional TMD materials prepared according to the method of the present invention, based on their intrinsic properties, can be effectively used in the manufacturing processes of various kinds of electronic devices. The method of the present invention has the potential for rapid, large-scale production for obtaining low-dimensional material suspension in high concentration for use in the development of nanotechnology.

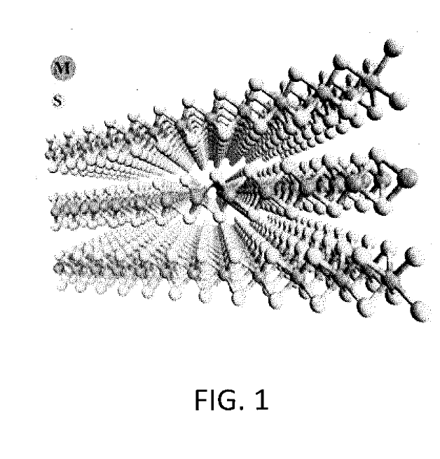

More importantly, the method of the present invention uses shear force to abrade the materials to be abraded. In accordance with yet another aspect of the present invention, where the material to be abraded is a TMD material, in which the pristine bulky material is formed by two-dimensional sheets stack through van der Waals interactions (as shown in FIG. 1, wherein M refers to a transition metal and S refers to a chalcogen), the shear force can overcome the van der Waals interactions between the adjacent layers in the pristine material, fractures and welds the layered materials, while the change in configuration does not affect the electrical properties of the materials. Therefore, products of different dimensional (i.e., zero-dimension to two-dimension) structures with better characteristics can be obtained by the method of the present invention via controlling the abrading conditions.

The present invention further provides a low-dimensional material suspension, characterized in that the suspension is obtained by mixing a pristine material to be abraded with an organic solvent followed by abrading the material to be abraded in the mixture by bead-milling. Moreover, the low-dimensional material suspension obtained according to the aforementioned method maintains good suspension stability and remains in a suspension state for six months. Such good suspension stability allows the low-dimensional material to be stably stored in the form of a suspension and able to be coated on a substrate by various common liquid processing methods such as spin-coating and ink-jetting for further preparation of low-dimensional material film and electronic devices comprising the low-dimensional materials.

The present invention further provides a method for the preparation of a low-dimensional material film, comprising forming a mixture by mixing a pristine material to be abraded with an organic solvent, abrading the material to be abraded in the mixture by bead-milling to obtain a suspension, coating the suspension on a substrate, and removing the organic solvent from the suspension to obtain the low-dimensional material film. The present invention further provides a low-dimensional material film prepared by the aforementioned method.

The present invention further provides a solar cell comprising the aforementioned low-dimensional TMD material film, wherein the film is used as an electron-extraction film

The following examples are to further describe the present invention. However, these examples should not be interpreted as limiting the scope of the present invention.

### Example 1

### Preparation of Low-Dimensional NbSe₂

Material Preparation:

The wet-milling machine for use is shown in FIG. 2. 50% of the inner space of the chamber of the wet-milling machine was filled with zirconia particles (having a particle size of 100 gm and a density>5.95 g/cm³). First, pristine NbSe₂ powder (99.9%; Alfa Aesear) was mixed with pure N-methyl-2-pyrolidinone (NMP, Macron Chemical, USA) at a concentration of 0.5 wt %. The mixture was fed to the chamber of the wet-milling machine. The peripheral speed of the rotor of the wet-milling machine was fixed at 2000 rpm and the pristine NbSe₂ was abraded by the zirconia particles, wherein the weight ratio of the zirconia particles to the pure N-methyl-2-pyrolidinone was 4:1. The fragmentation of the pristine NbSe₂ resulted from the strong stress upon the collision of colliding zirconia particles (frontal collisions in straining regions or oblique collisions induced by a local shear).

A double water-cooled jacket in the wet-milling machine allowed the temperature inside the wet-milling machine to be controlled during the abrasion process. The suspension obtained was purified without any contamination from the zirconia particles, due to the highly dense zirconia precipitating readily to the bottom of the chamber of the wet-milling machine after abrasion.

### Example 2

### Characterization of Low-Dimensional NbSe₂

Characterization:

The abraded NbSe₂ suspension was diluted ten-fold with isopropanol (IPA); drops of the solution were placed on a holey carbon-coated copper grid (Lacey Carbon Type-A 300 mesh copper grid; TED Pella) or Si/SiO₂ surface and then dried in air at 70° C. prior to characterization using SEM (FEI Nova200) and Raman spectroscopy (NT-MDT confocal Raman microscopic system; exciting laser wavelength: 514 nm; laser spot size: 0.5 μm).

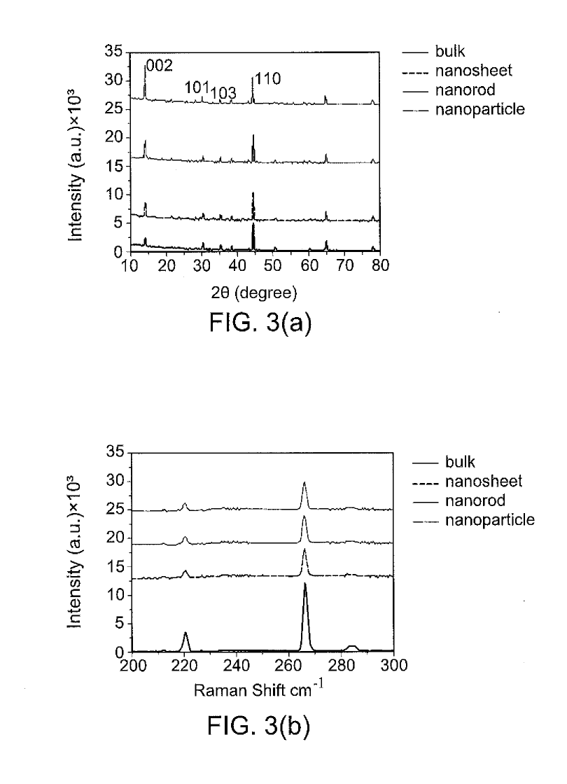

TMD powders before and after abrasion were characterized using XRD (PANalytical). The results are shown in FIG. 3. FIG. 3(a) shows Powder XRD patterns of pristine NbSe₂ and resulting nanosheets, nanorods and nanoparticles (hexagonal; JCPDS: 01-089-4313; a=b=3.4 Å; c=12.547 Å). Periodicity in the c-axis is evident for the pristine NbSe₂ material, with a strong (002) peak observed at a value of 2θ of 14°. FIG. 3(b) shows the Raman spectra of pristine NbSe₂, NbSe₂ nanosheet, nanorods, and nanoparticles. The samples were prepared by placing drops of the aforementioned dispersions diluted ten-fold with IPA onto a Si/SiO₂ surface and drying under ambient atmosphere at 70° C. for 10 min and then conducting measurements.

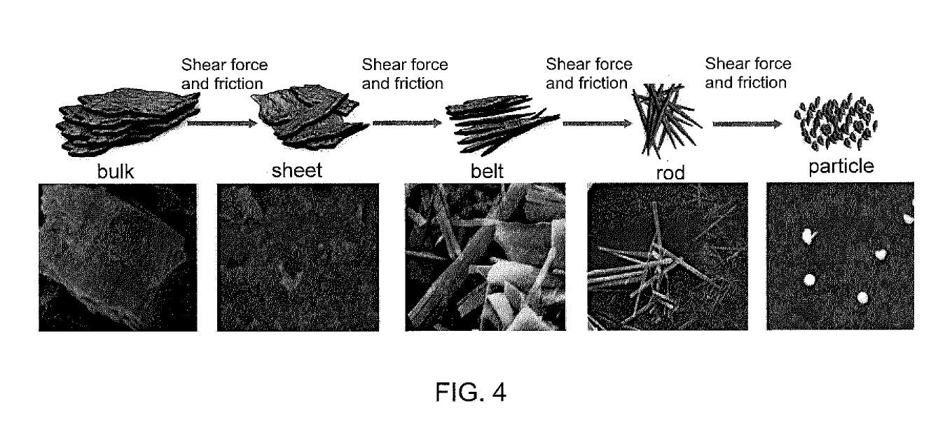

FIG. 4 shows the SEM images of pristine NbSe₂, NbSe₂ nanosheet, nanorods, and nanoparticles.

Conductivity Test:

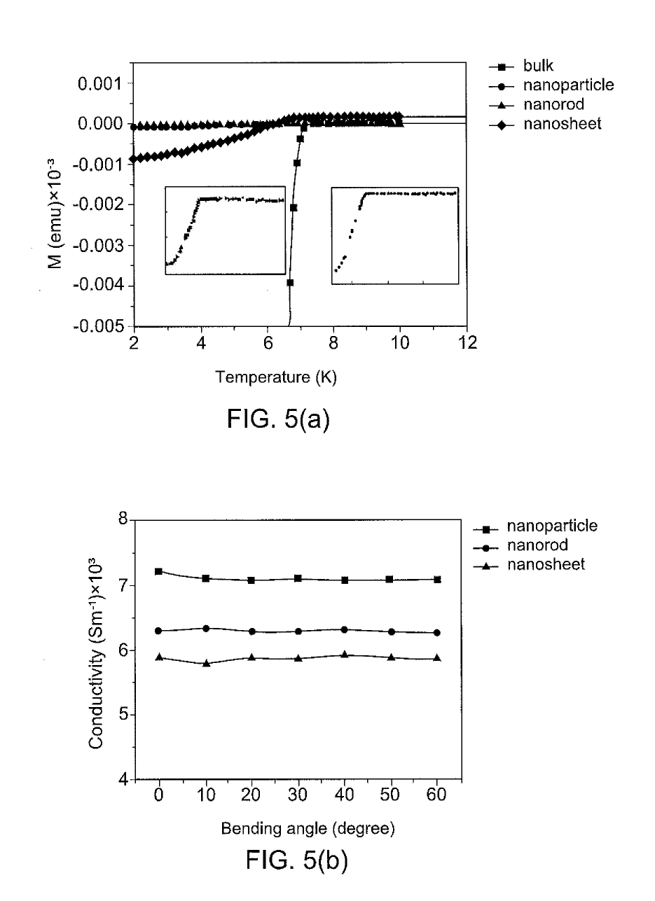

The conductivity test was carried out by first preparing a thin film by spray-coating on a PET substrate the pristine NbSe₂, NbSe₂ nanosheet, nanorods, and nanoparticles dispersions diluted ten-fold with IPA and drying under ambient atmosphere at 70° C. for 10 min, followed by using the van der Pauw four-point probe technique with a Hall effect measurement system (Ecopia, HMS 5000). The thickness of the thin film can be changed by changing the time for spray-coating. The electrical measurement results are as shown in FIG. 5. FIG. 5(a) shows the magnetic susceptibility plotted with respect to temperature for the pristine NbSe₂, the NbSe₂ nanosheets, nanorods and nanoparticles. Inset: magnified view of the superconductivity transition for the NbSe₂ nanorods (left) and nanoparticles (right). FIG. 5(b) shows the conductivity change of a thin film of the NbSe₂ nanosheets, nanorods and nanoparticles on a PET substrate, plotted with respect to the bending angle. It can be seen from FIG. 5(b) that the films exhibited high flexibility and mechanical strength in the bending test (having a conductivity of 5.88 and 5.85 S/cm) by maintaining a comparable conductance before and after performing the bending test cycle. FIG. 5(c) shows the transmission spectra of films of the NbSe₂ nanosheets, nanorods and nanoparticles measured by Jasco V-670 UV-Vis-NIR spectrophotometer. Inset: photographs of the (1) bare PET substrate, (2) film of NbSe₂ nanoparticles on PET, (3) film of NbSe₂ nanorods on PET, and (4) film of NbSe₂ nanosheets on PET. FIGS. 5(d) and (e) show the representative photograph of a NbSe₂ nanosheets film coated-flexible electrode subjected to bending, wherein the bending angle of the PET film in FIG. 5(e) is larger than 60°. It can be seen from the conductance measurement result that even under the condition where the bending angle is larger than 60°, the conductance still remains comparably stable. That is, the low-dimensional NbSe₂ film prepared by the method of the present invention has high strength and excellent flexibility.

### Example 3

### Preparation of Low-Dimensional WS₂ and MoS₂

WS₂ (powder, 99%; Sigma-Aldrich) and MoS₂ (powder, 99%; Sigma-Aldrich) were used for the preparation of pristine WS₂ and MoS₂ mixtures, respectively, according to the same method as described in Example 1, with the exception that the organic solvent used was ethylene glycol (J. T. Baker), and wherein the concentration of the pristine WS₂ or MoS₂ was 1 wt %. The mixtures were fed to the chamber of the wet-milling machine. The peripheral speed of the rotor was fixed at 2000 rpm and the pristine mixtures were abraded by the zirconia beads, wherein the weight ratio of the zirconia particles to the ethylene glycol was 4:1. Dark green suspensions were obtained after abrasion.

### Example 4

### Characterization of Low-Dimensional WS₂ and MoS₂

The abraded suspension of the WS₂ suspension was diluted ten-fold with methanol (Aldrich); drops of the solution were placed on a holey carbon-coated copper grid (Lacey Carbon Type-A 300 mesh copper grid; TED Pella) or Si/SiO₂ surface and then dried in air at 70° C. prior to characterization using SEM (FBI Nova200) and Raman spectroscopy (NT-MDT confocal Raman microscopic system; exciting laser wavelength: 514 nm; laser spot size: 0.5 μm).

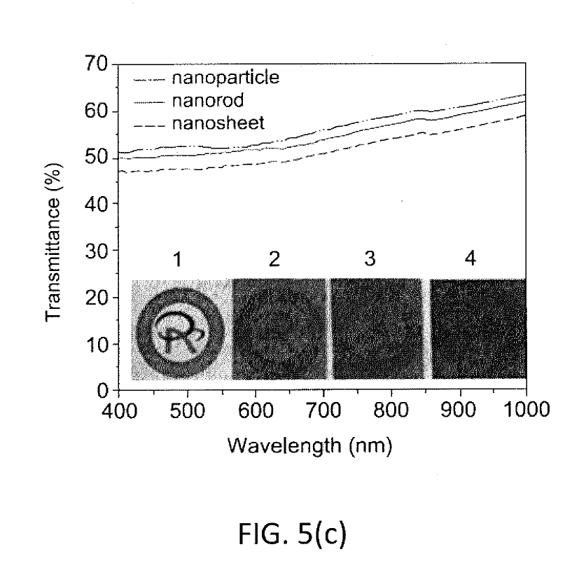

TMD powders before and after abrasion were characterized using XRD (PANalytical). The results are shown in FIG. 6. FIG. 6(a) shows Powder XRD patterns of pristine WS₂ and resulting nanosheets. FIG. 6(b) Powder XRD patterns of pristine MoS₂ and resulting nanosheets. Periodicity in the c-axis is evident for the pristine WS₂ and MoS₂ materials, with a strong (002) peak observed at a value of 2θ of 14° as shown in FIGS. 6(a) and (b).

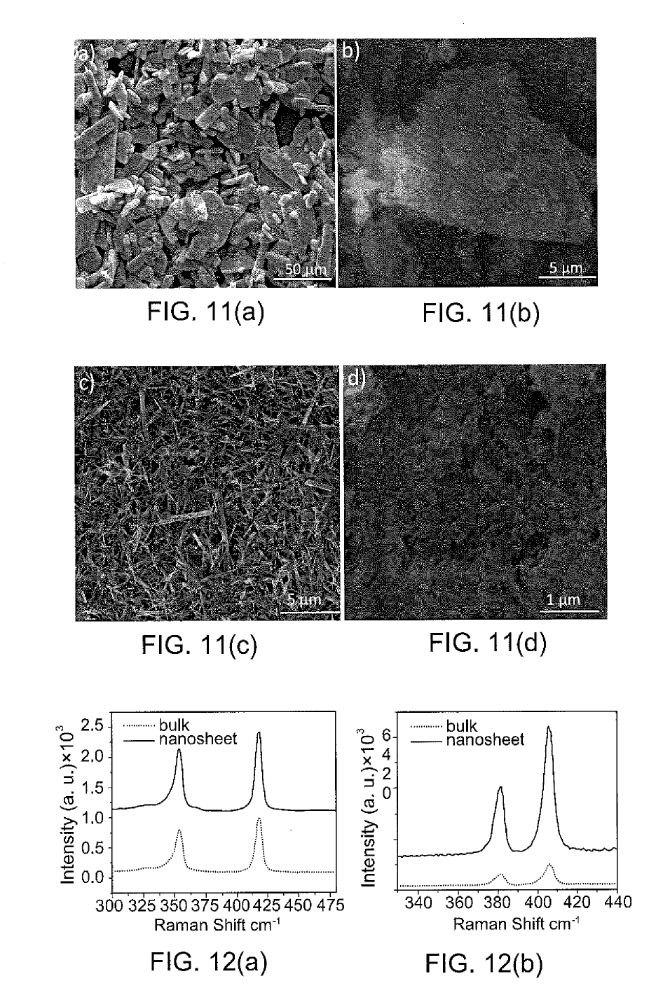

FIGS. 12(a) and (b) show the Raman spectra of pristine WS₂ and MoS₂, and WS₂ and MoS₂ nanosheets, respectively (λ_{excitation}=473 nm). The samples were prepared by placing drops of the aforementioned suspensions diluted ten-fold with methanol onto a Si/SiO2 surface and drying under ambient atmosphere at 70° C. for 10 min after which measurements were conducted.

### Example 5

### Electrical Tests of Low-Dimensional WS₂ and MoS₂

This experiment is directed to the preparation of solar cell devices comprising WS₂ and MoS₂, respectively, and the electrical tests of the devices, wherein the WS₂ and MoS₂ layers serve as the electron extraction layers in the solar cell devices of this experiment.

Prior to spin-coating a thin WS₂ or MoS₂ film, ITO substrates (<10 Ωsq⁻¹; RiTdisplay) were cleaned through sonication in detergent-containing water and twice with deionized water (15 min each), dried in an oven overnight, and then treated with UV/ozone for 15 min. An ethylene glycol suspension of WS₂ (MoS₂) was spun onto the ITO substrate at 2000 rpm for 60 s and then the sample was thermally annealed at 150° C. for 60 min in air on a hot plate. Poly(3-hexylthiophene) (P3HT, Rieke Specialty Polymer), PCBM (>99%; Solenne), V₂O₅ and aluminum (Al; 99.999%; Admat Midas) were used therewith to prepare a solar cell device to undergo electrical tests. The solar cell device featuring a WS₂ (MoS₂) interfacial layer was prepared in an inverted ITO-WS₂ (MoS₂)—P3HT:PCBM-V₂O₅—Al structure, wherein the active layer (P3HT:PCBM) of the device was spin-coated from a solution containing P3HT:PCBM (1:1, w/w) in 1,2-dichlorobenzene (DCB; Aldrich) on top of the WS₂ (MoS₂) film and dried for 30 min in a covered Petri glass dish (solvent evaporation); the films were then annealed at 130° C. for 30 minutes. The thickness of the active layer was about 200 nm. Layers of V₂O₅ (10 nm) and Al (100 nm) were thermally evaporated through a shadow mask under vacuum (<10⁻⁶ Torr). The active area of each device was 10 mm². The control device was a solar cell device using ZnO as the electron extraction layer.

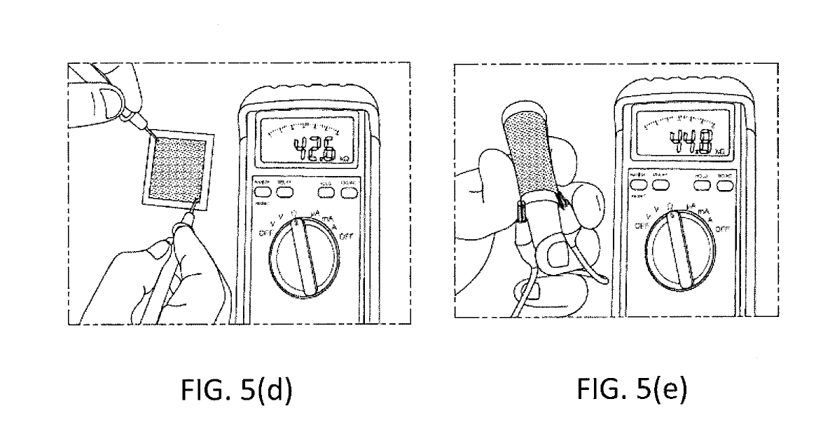

The electrical test of the solar cell prepared according to the aforementioned steps is shown in FIG. 7, in which FIG. 7(a) is a current density-voltage (J-V) plot. The following Table 1 shows the performance results for the solar cell devices. Voc refers to open-circuit voltage, Jsc refers to short-circuit current density; FF refers to filling factor, PCE refers to power conversion efficiency, and Rs refers to lower series resistances, which is obtained by the dark J-V curves characteristics shown in the inset of FIG. 7(a).

TABLE 1

| Buffer layer | V_{oc} (V) | J_{sc} (mA cm⁻²) | FF (%) | PCE (%) | Rₛ (Ω)^{a} |
|---|---|---|---|---|---|
| WS₂ | 0.58 | 9.31 | 55.28 | 2.98 | 2.85 |
| MoS₂ | 0.58 | 11.19 | 51.6 | 3.35 | 0.96 |

FIG. 7(b) shows the stability of solar cell devices featuring WS₂ and MoS₂ as electron extraction layers, measured in terms of PCE over time. Inset is the inverted device structure.

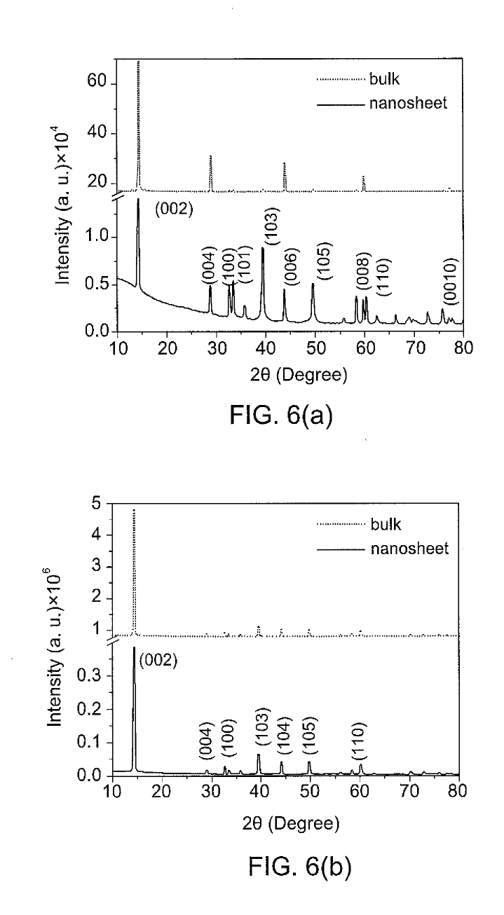

It can be seen from FIGS. 7(a) and (b) that, compared to the control device, the solar cell devices featuring WS₂ or MoS₂ film as electron extraction layers exhibit lower open-circuit voltages, due to the use of the WS₂ or MoS₂ films as the electron extraction layers at the anode of the solar cell devices that reduce the extraction barrier heights and reduce the recombination of electrons and holes at the electrodes, which lead to the increase of the photocurrent extraction and the reduction of open-circuit voltage. Compared to the solar cell device featuring WS₂ film, the solar cell device featuring MoS₂ film has a higher short-circuit current density, which is because MoS₂ has a higher conductivity, lower series resistance (measured from the dark J-V curves characteristics) and lower absorption coefficient than WS₂ (as shown in the UV absorption spectra of WS₂ (FIG. 8(a) and MoS₂ (FIG. 8(b) films on the ITO substrates).

### Example 6

### Preparation of Low-Dimensional Graphene

Graphite (Bay Carbon Inc. SP-1) was used for the preparation of the pristine graphite mixture by the same method as that disclosed in Example 1, wherein the organic solvent used was pure N-methyl-2-pyrolidinone (NMP, Macron Chemical, USA) and the concentration of the pristine graphite was 0.25 wt %. Moreover, 60% of the inner space of the chamber of the wet-milling machine was filled with zirconia particles (having a particle size of 200 μm and a density>5.95 g/cm³). The mixture was fed to the chamber of the wet-milling machine. The peripheral speed of the rotor of the wet-milling machine was fixed at 2000 rpm and the pristine mixture was abraded by the zirconia particles, wherein the weight ratio of the zirconia particles to the pure N-methyl-2-pyrolidinone was 4:1.

### Example 7

### Characterization of Low-Dimensional Graphene

A sample of the abraded graphene was prepared according to the same method described in Example 2. SEM (FEI Nova 2000) was used to observe its morphology changes.

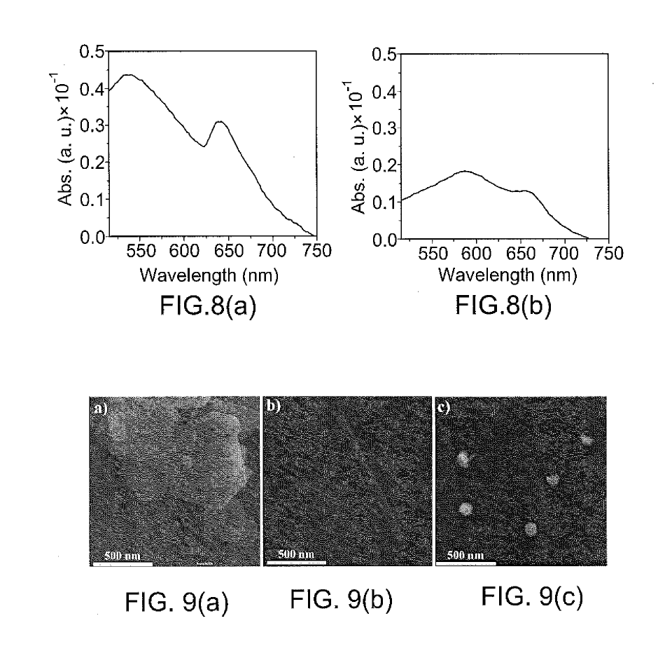

FIGS. 10(a), (b) and (c) are SEM images of pristine graphite, graphene nanosheets and nanoparticles. The thickness of the pristine graphite is >100 m. The lateral dimension of the graphene nanosheets is from 1 to 5 μm. The average particle size of the graphene nanoparticles is 30 to 150 nm.

### Example 8

### Preparation of Low-Dimensional MoO₃

MoO₃ (99.5%; Alfa Aesar) was used for the preparation of the pristine MoO₃ mixture by the same method as that disclosed in Example 1, with the exception that the organic solvent used was pure IPA (Aldrich), and wherein the concentration of MoO₃ was 5 wt %. Moreover, 60% of the inner space of the chamber of the wet-milling machine was filled with zirconia particles (having a size of 200 μm and a density>5.95 g/cm³). The mixture was fed to the chamber of the wet-milling machine. The peripheral speed of the rotor of the wet-milling machine was fixed at 2000 rpm and the pristine mixture was abraded by the zirconia particles, wherein the weight ratio of the zirconia particles to the pure IPA was 4:1.

### Example 9

### Characterization of Low-Dimensional MoO₃

A sample of the abraded MoO₃ was prepared according to the same method described in Example 2. SEM (FEI Nova 2000) was used to observe its morphology changes.

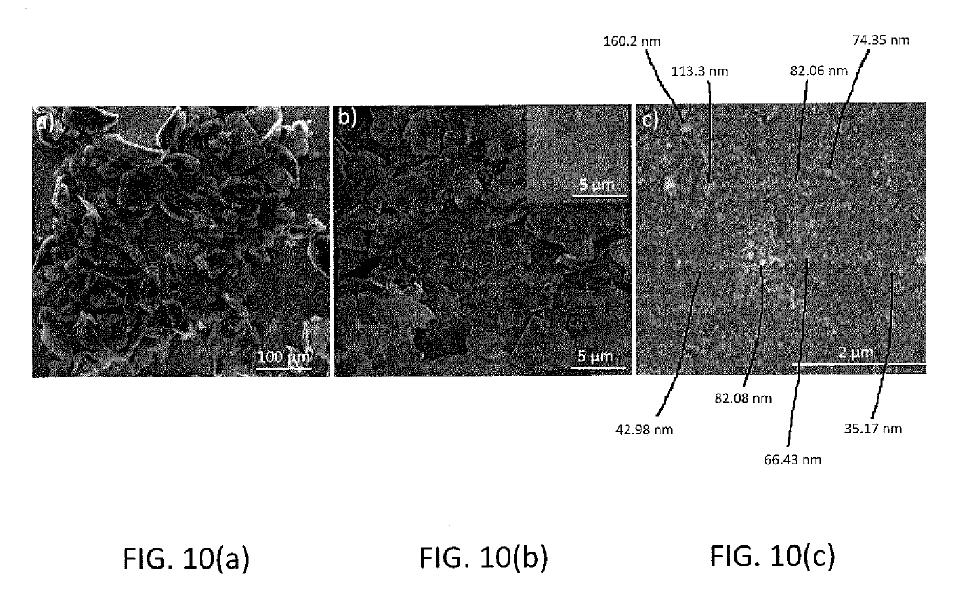

FIGS. 11(a), (b), (c) and (d) are SEM images of pristine graphite, graphene nanosheets, nanorods and nanoparticles. The thickness of the pristine MoO₃ is >50 μm. The lateral dimension of the MoO₃ nanosheets is from 2 to 10 μm. The length of the MoO₃ nanorods is up to 5 μm. The average particle size of the MoO₃ nanoparticles is 100 to 500 nm.

1. A method for the preparation of low-dimensional materials, comprising:
(i) mixing a pristine material to be abraded with an organic solvent to form a mixture;
(ii) abrading the material to be abraded in the mixture by bead-milling,
(iii) obtaining a suspension comprising the material of low dimension and the organic solvent; and
(iv) removing the organic solvent from the suspension to obtain the low-dimensional material.

2. The method according to claim 1, wherein in step (ii), the bead-milling is carried out by feeding the mixture into a wet-milling machine with abrading beads for abrasion, and the amount of the abrading beads in the inner space of the wet-milling machine is about 30% to 80%.

3. The method of claim 1, wherein the abrading beads are ceramic beads.

4. The method of claim 2, wherein the ratio of the abrading beads and the solvent in step (ii) is 5:1 to 1:1.

5. The method of claim 4, wherein the ratio of the abrading beads and the solvent in step (ii) is 4:1 to 3:1.

6. The method of claim 2, wherein the size of the abrading beads is from 20 μm to 1 mm.

7. The method of claim 6, wherein the size of the abrading beads is from 20 μm to 200 μm.

8. The method of claim 7, wherein the size of the abrading beads is from 50 μm to 100 μm.

9. The method according to claim 1 wherein the rate of the rotating blades of the wet-milling machine is from 10 to 6000 rpm, preferably 1000 to 3000 rpm, and more preferably 1500 to 2000 rpm.

10. The method according to claim 1 wherein the time for abrasion is from 30 minutes to 840 minutes.

11. The method of claim 10, wherein the time for abrasion is from 60 minutes to 600 minutes.

12. The method according to claim 1 wherein the organic solvent is selected from the group consisting of ethylene glycol, N-methylpyrrolidone, isopropanol, and combinations thereof.

13. The method of claim 12, wherein the organic solvent is selected from N-methylpyrrolidone or isopropanol.

14. The method according to claim 1 wherein the material to be abraded is a transition metal dichalcogenide, metal oxide, or carbonaceous material.

15. A low-dimensional material suspension characterized in that the suspension is obtained by forming a mixture comprising a pristine material to be abraded and an organic solvent, and abrading the material to be abraded in the mixture by bead-milling.

16. A method for the preparation of a low-dimensional material film, comprising coating the suspension obtained in step (iii) of claim 1 and removing the solvent thereof to obtain a low-dimensional material film.

17. A low-dimensional material film obtained by the method of claim 16.

18. A solar cell device, comprising:
an anode,
a cathode, and
a low-dimensional TMD material film prepared according to the method of claim 16, wherein the film is placed between the anode and the cathode.
